(19) United States
(12) Patent Application Publication
(10) Pub. No.: US 2011/0220178 A1
(43) Pub. Date: Sep. 15, 2011

(54) ASSEMBLIES COMPRISING A THERMALLY AND DIMENSIONALLY STABLE POLYIMIDE FILM, AN ELECTRODE AND A LIGHT ABSORBER LAYER, AND METHODS RELATING THERETO

(75) Inventors: Kostantinos KOURTAKIS, Media, PA (US); Brian C. AUMAN, Pickerington, OH (US); Salah BOUSSAAD, Wilmington, DE (US)

(73) Assignee: E. I. DU PONT DE NEMOURS AND COMPANY, Wilmington, DE (US)

(21) Appl. No.: 12/883,806

(22) Filed: Sep. 16, 2010

Related U.S. Application Data
(60) Provisional application No. 61/243,404, filed on Sep. 17, 2009.

(51) Int. Cl. H01L 31/042; H01L 31/0272

(52) U.S. Cl. 136/249; 136/252; 136/262

(57) ABSTRACT

The assemblies of the present invention comprise an electrode, an light absorber layer and a polyimide film. The polyimide film contains from about 40 to about 95 weight percent of a polyimide derived from: i. at least one aromatic dianhydride, at least about 85 mole percent of such aromatic dianhydride being a rigid rod type dianhydride, and ii. at least one aromatic diamine, at least about 85 mole percent of such aromatic diamine being a rigid rod type diamine. The polyimide films of the present disclosure further comprise a filler that: i. is less than about 100 nanometers in all dimensions; and ii. is present in an amount from about 5 to about 60 weight percent of the total weight of the polyimide film.

### FIELD OF DISCLOSURE

This disclosure relates generally to assemblies comprising a light absorber layer, an electrode, and a polyimide film, where the polyimide film has: i. advantageous dielectric properties; ii. advantageous thermal and dimensional stability over a broad temperature range, even in the presence of tension or other dimensional stress; and iii. advantageous adhesion properties to metal. More specifically, the assemblies of the present disclosure are well suited for the manufacture of monolithically integrated solar cells, particularly monolithically integrated solar cells comprising a copper/indium/gallium/di-selenide (CIGS) or similar-type light absorber layer.

### BACKGROUND OF THE DISCLOSURE

To address an increasing need for alternative energy sources, there is currently a strong interest in developing light-weight, efficient photovoltaic systems (e.g., photovoltaic cells and modules). Of particular interest are photovoltaic systems having a copper/indium/gallium/di-selenide (CIGS) light absorber layer. With such systems, a high temperature deposition/annealing step is generally applied to improve light absorber layer performance. The annealing step is typically conducted during manufacture and is typically applied to an assembly, comprising a substrate, a bottom electrode and the CIGS light absorber layer. The substrate requires thermal and dimensional stability at the annealing temperature(s), and therefore conventional substrates have typically comprised metal or ceramic (conventional polymeric materials tend to lack sufficient thermal and dimensional stability, particularly at peak annealing temperatures). However, ceramics, such as glass, lack flexibility and can be heavy, bulky and subject to breakage. Metals can be less prone to such disadvantages, but metals tend to conduct electricity, which tends to also be a disadvantage, e.g., inhibits monolithic integration of CIGS photovoltaic cells. The substrate serves as a support upon which a bottom electrode (such as, a molybdenum electrode) is formed. Therefore, good adhesion between the bottom electrode and the substrate is required.

Hence, there exists a need for CIGS type assemblies comprising a polymeric substrate having sufficient thermal and dimensional stability (and also sufficient dielectric properties), that the assembly: (a) can be manufactured by a relatively economical process, such as, reel-to-reel or similar-type processing, (b) enables relatively simple, straightforward monolithic integration of thin film photovoltaic cells, e.g., by reel-to-reel or similar type manufacturing processes, (c) can adequately tolerate desired deposition/annealing temperatures during fabrication of the assembly and (d) has good adhesion between the bottom electrode and/or the substrate.

### SUMMARY

The assemblies of the present disclosure comprise a polyimide film having a thickness from about 8 to about 150 microns. The polyimide film contains from about 40 to about 95 weight percent of a polyimide derived from: i. at least one aromatic dianhydride, at least about 85 mole percent of such aromatic dianhydride being a rigid rod type dianhydride, ii. at least one aromatic diamine, at least about 85 mole percent of such aromatic diamine being a rigid rod type diamine. The polyimide films of the present disclosure further comprise a filler, where: i. the filler has an average diameter of less than about 100, 90, 80, 70, 60, 50, 40, 30, 25 or 20 nanometers in all dimensions; ii. the filler is present in an amount from about 5 to about 60 weight percent of the total weight of the polyimide film. The assemblies of the present disclosure further comprise a light absorber layer and an electrode, where the electrode is between the light absorber layer and the polyimide film, and the electrode is in electrical communication with the light absorber layer.

### BRIEF DESCRIPTION OF THE DRAWINGS

FIG. 1 is a sectional view of a thin-film solar cell fabricated on a polyimide film, constructed in accordance with the present disclosure.

FIG. 2 illustrates an electron micrograph picture depicting a metal-polyimide interface of the metalized polyimide of Example 1.

FIG. 3 illustrates an electron micrograph picture depicting a highly magnified metal-polyimide interface of the metalized polyimide of Example 2.

FIG. 4 illustrates an electron micrograph picture depicting a metal-polyimide interface of the metalized polyimide of Example 3.

FIG. 5 illustrates an electron micrograph picture depicting a metal-polyimide interface of the metalized polyimide of Example 4.

FIG. 6 illustrates an electron micrograph picture depicting a metal-polyimide interface of the metalized polyimide of Comparative Example A.

FIG. 7 illustrates an electron micrograph picture depicting a metal-polyimide interface of the metalized polyimide of Comparative Example B.

### DETAILED DESCRIPTION

### Definitions

“Film” is intended to mean a free-standing film or a coating on a substrate. The term “film” is used interchangeably with the term “layer” and refers to covering a desired area.

“Monolithic integration” is intended to mean integrating (either in series or in parallel) a plurality of photovoltaic cells to form a photovoltaic module, where the cells/module can be formed in a continuous fashion on a single film or substrate, e.g., a reel to reel operation.

“GIGS/CIS” is intended to mean a light absorber layer, either on its own or as part of a combination of layers, such as, in combination with an electrode, or in combination with an electrode and a polyimide film, or as part of a photovoltaic cell or module, (depending upon context) where the light absorber layer (or at least one light absorber layer) comprises: i. a copper indium gallium di-selenide composition; ii. a copper indium gallium disulfide composition; iii. a copper indium di-selenide composition; iv. a copper indium disulfide composition; or v. any element or combination of elements that could be substituted for copper, indium, gallium, di-selenide, and/or disulfide, whether presently known or developed in the future.

“Dianhydride” as used herein is intended to include precursors or derivatives thereof, which may not technically be a dianhydride but would nevertheless react with a diamine to form a polyamic acid which could in turn be converted into a polyimide.

Similarly, “diamine” as used herein is intended to include precursors or derivatives thereof, which may not technically be a diamine but would nevertheless react with a dianhydride to form a polyamic acid which could in turn be converted into a polyimide.

As used herein, the terms “comprises,” “comprising,” “includes,” “including,” “has,” “having” or any other variation thereof, are intended to cover a non-exclusive inclusion. For example, a method, process, article, or apparatus that comprises a list of elements is not necessarily limited to only those elements but may include other elements not expressly listed or inherent to such method, process, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

Also, articles “a” or “an” are employed to describe elements and components of the invention. This is done merely for convenience and to give a general sense of the invention. This description should be read to include one or at least one and the singular also includes the plural unless it is obvious that it is meant otherwise.

The polyimide films used in the assemblies of the present disclosure resist shrinkage or creep (even under tension, such as, reel to reel processing) within a broad temperature range, such as, from about room temperature to temperatures in excess of 400° C., 425° C. or 450° C. In one embodiment, the support film changes in dimension by less than 1, 0.75, 0.5, or 0.25 percent when subjected to a temperature of 460° C. for 30 minutes while under a stress in a range from 7.4-8.0 MPa (megapascals). In some embodiments, the polyimide films have sufficient dimensional and thermal stability to be a viable alternative to metal or ceramic support materials. An additional advantage of the assemblies of the present disclosure is improved adherence of the polyimide film to the electrode.

The assemblies of the present disclosure can be used, for example, in thin film solar cells. When used in a CIGS/CIS application, the polyimide films of the present disclosure can provide a thermally and dimensionally stable, flexible polyimide film (support) upon which a bottom electrode (such as, a molybdenum electrode) can be directly formed on the polyimide film surface. Over the bottom electrode, a light absorber layer can be applied in a manufacturing step toward the formation of a CIGS/CIS photovoltaic cell. In some embodiments, the light absorber layer is a CIGS/CIS light absorber layer. In some embodiments, the polyimide film can also be coated on both sides with the electrode metal even if only one metal side is used as the electrode on which the light absorber layer is deposited.

In some embodiments, the bottom electrode is flexible. The polyimide film can be reinforced with thermally stable, inorganic: fabric, paper (e.g., mica paper), sheet, scrim or combinations thereof. In some embodiments, the polyimide film of the present disclosure has adequate electrical insulation properties to allow multiple CIGS/CIS photovoltaic cells to be monolithically integrated into a photovoltaic module. In some embodiments, the assembly further comprises a plurality of monolithically integrated CIGS/CIS photovoltaic cells. In some embodiments, the polyimide films of the present disclosure provide:
i. low surface roughness, i.e., an average surface roughness (Ra) of less than 400, 350, 300, 275 or 100 nanometers;
ii. low levels of surface defects; and/or
iii. other useful surface morphology,
   to diminish or inhibit unwanted defects, such as, electrical shorts.

In one embodiment, the polyimide films used in the assemblies of the present disclosure have an in-plane CTE in a range between (and optionally including) any two of the following: 1, 5, 10, 15, 20, 25, 30, 35 and 40 ppm/° C., where the in-plane coefficient of thermal expansion (CTE) is measured between 50° C. and 350° C. In some embodiments, the CTE within this range is further optimized to further diminish or eliminate unwanted cracking due to thermal expansion mismatch of any particular supported material selected in accordance with the present disclosure (e.g., the CIGS/CIS light absorber layer in CIGS/CIS applications). Generally, when forming the polyimide, a chemical conversion process (as opposed to a solely thermal conversion process) will provide a lower CTE polyimide film. Chemical conversion processes for converting polyamic acid into polyimide are well known and need not be further described here. The thickness of a polyimide film can also impact CTE, where thinner films tend to give a lower CTE (and thicker films, a higher CTE), and therefore, film thickness can be used to fine tune film CTE, depending upon any particular application selected. The polyimide films used in the assemblies of the present disclosure have a thickness in a range between (and optionally including) any of the following thicknesses (in microns): 8, 10, 12, 15, 20, 25, 50, 75, 100, 125 and 150 microns. Monomers and fillers within the scope of the present disclosure can also be selected or optimized to fine tune CTE within the above range. Ordinary skill and experimentation may be necessary in fine tuning any particular CTE of the polyimide films of the present disclosure, depending upon the particular application selected for the assemblies.

The polyimide films used in the assemblies of the present disclosure should have high thermal stability so the films do not substantially degrade, lose weight, have diminished mechanical properties, or give off significant volatiles, e.g., during the light absorber layer deposition and/or annealing process in a CIGS/CIS application of the present disclosure. In a CIGS/CIS application, in one embodiment the polyimide film should be thin enough to not add excessive weight to the photovoltaic module, but thick enough to provide high electrical insulation at operating voltages, which in some cases may reach 400, 500, 750 or 1000 volts or more.

In accordance with the present disclosure, a filler is added to the polyimide film to improve adhesion to metal. In some embodiments, the filler increases the storage modulus above the glass transition temperature (Tg) of the polyimide film. The addition of filler typically allows for the retention of mechanical properties at high temperatures and can improve handling characteristics. The fillers of the present disclosure:
1. have a average diameter of less than (as a numerical average) 100 nanometers (and in some embodiments, less than 80, 75, 65, 60, 55, 50, 45, 40, 35, 30, 25, or 20 nanometers) in all dimensions; and
2. is present in an amount between and optionally including any two of the following percentages: 5, 10, 15, 20, 25, 30, 35, 40, 45, 50, 55, and 60 weight percent, based upon the total weight of the polyimide film.

Suitable fillers are generally stable at temperatures above 450° C., and in some embodiments do not significantly decrease the electrical insulation properties of the polyimide film. The nanoparticle fillers of the present disclosure can be any shape, including spherical and oblong. In one embodiment, the particle filler is relatively uniform in size and is substantially non-aggregated. The filler particle can be hollow, porous, or solid.

In one embodiment, the nanoparticles of the present disclosure are inorganic oxides, such as but not limited to silicon oxide (nanosilica), titanium oxide, aluminum oxide, zirconium oxide, and binary, ternary, quaternary and higher order composite oxides of one or more cations selected from silicon, titanium, aluminum and zirconium. More than one type of nanoparticle may be used in any combination. In one embodiment, nanoparticle composites (e.g. single or multiple core/shell structures) can be used, in which one oxide encapsulates another oxide in one particle.

In some embodiments, at least 70, 80, 90, 95, 97, 98, 99 or 100 weight percent of the filler comprises an inorganic oxide. In one embodiment, solid nanosilica particles of the present disclosure are produced from sols of silicon oxides (e.g., colloidal dispersions of solid silicon nanoparticles in liquid media), especially sols of amorphous, semi-crystalline, and/or crystalline silica. Such sols can be prepared by a variety of techniques and in a variety of forms, which include hydrosols (where water serves as the liquid medium), organosols (where organic liquids serve as the liquid medium), and mixed sols (where the liquid medium comprises both water and an organic liquid), see for example, U.S. Pat. Nos. 4,522,958; and 5,648,407. In one embodiment, the particle filler is suspended in a polar, aprotic solvent, such as, DMAC or other solvent compatible with polyamic acid. In another embodiment, solid nanosilica particles can be commercially obtained as colloidal dispersions or sols dispersed in polar aprotic solvents, such as for example Nissan DMAC-ST, a solid silica colloid in dimethylacetamide containing <0.5 percent water, median nanosilica particle diameter d₅₀ of about 16 nm, 20-21 wt % silica, available from Nissan Chemicals America Corporation, Houston, Tex., USA.

Porous nanosilica particles can be used alone, or as a mixture with other nanoparticles to form the polyimide composite. A porous nanoparticle comprises at least one portion of a lower density material, such as air, and in one embodiment can be a shell of silicon oxide (e.g., a hollow nanosilica particle). Methods for producing hollow nanosilica particles are known, for example, as described in JP-A-2001/233611 and JP-A-2002/79616.

In some embodiments, the filler is an inorganic oxide, and the polyimide film has the following properties: (i) a Tg greater than 300° C., (ii) a dielectric strength greater than 500 volts per 25.4 microns, (iii) an isothermal weight loss under inert conditions of less than 2% at 500° C. over 30 minutes, and (iv) an emax of less than 1.05% at 7.4-8 MPa.

In some embodiments, the filler is coated with a coupling agent. In some embodiments, the filler is coated with an aminosilane coupling agent. In some embodiments, the filler is coated with a dispersant. In some embodiments, the filler is coated with a combination of a coupling agent and a dispersant. Alternatively, the coupling agent, dispersant or a combination thereof can be incorporated directly into the polyimide film and not necessarily coated onto the filler.

In some embodiments, a filtering system is used to ensure that the final polyimide film will not contain discontinuous domains greater than the desired maximum filler size. In some embodiments, the filler is subjected to intense dispersion energy, such as agitation and/or high shear mixing or media milling or other dispersion techniques, including the use of dispersing agents, when incorporated into the polyimide film (or incorporated into a film precursor) to inhibit unwanted agglomeration above the desired maximum filler size.

Generally speaking, film smoothness is desirable, since surface roughness: i. can interfere with the functionality of the layer or layers deposited on top, ii. can increase the probability of electrical or mechanical defects, and iii. can diminish property uniformity along the film. In one embodiment, the filler (and any other discontinuous domains) are sufficiently dispersed during film formation, such that the filler (and any other discontinuous domains) are sufficiently between the surfaces of the film upon film formation to provide a final polyimide film having an average surface roughness (Ra) of less than 400, 350, 300, 275 or 100 nanometers. Surface roughness as provided herein can be determined by optical surface profilometry to provide Ra values, such as, by measuring on a Veeco Wyco NT 1000 Series brand surface roughness instrument in VSI mode at 25.4× or 51.2× utilizing Wyco Vision 32 brand analytical software.

In some embodiments, the filler is chosen so that it does not itself degrade or produce off-gasses at the desired processing temperatures. Likewise in some embodiments, the filler is chosen so that it does not contribute to degradation of the polymer.

Polyimides used in the assemblies of the present disclosure are derived from: i. at least one aromatic diamine, at least 85, 90, 95, 96, 97, 98, 99, 99.5 or 100 mole percent being a rigid rod type monomer; and ii. at least one aromatic dianhydride, at least 85, 90, 95, 96, 97, 98, 99, 99.5 or 100 mole percent being a rigid rod type monomer. Suitable rigid rod type, aromatic diamine monomers include: 1,4-diaminobenzene (PPD), 4,4′-diaminobiphenyl, 2,2′-bis(trifluoromethyl)benzidene (TFMB), 1,4-naphthalenediamine, 2,5-diaminotoluene, 4,4′-diaminobenzanilide and/or 1,5-naphthalenediamine. Suitable rigid rod type, aromatic dianhydride monomers include pyromellitic dianhydride (PMDA), 2,3,6,7-naphthalene tetracarboxylic dianhydride and/or 3,3′,4,4′-biphenyl tetracarboxylic dianhydride (BPDA). In some embodiments, at least 50 mole percent of the aromatic diamine is 1,5-naphthalenediamine.

Monomers having a freedom of rotational or bending movement (once polymerized into a polyimide) substantially equal to or less than the above examples (of rigid rod diamines and rigid rod dianhydrides) are intended to be deemed rigid rod monomers for purposes of this disclosure.

Non-rigid rod monomers for purposes of this disclosure are intended to mean aromatic monomers capable of polymerizing into a polyimide backbone structure having substantially greater freedom of movement compared to the rigid rod monomers described and exemplified above. The non rigid rod monomers, when polymerized into a polyimide, provide a backbone structure having a bend or otherwise are not co-linear along the polyimide backbone they create (e.g., are not about 180°). Examples of non-rigid rod monomers in accordance with the present disclosure include any diamine and any dianhydride capable of providing a rotational or bending bridging group along the polyimide backbone. Examples of rotational or bending bridging groups include —O—, —S—, —SO₂—, —C(O)—, —C(CH₃)₂—, —C(CF₃)₂—, and —C(R,R′)— where R and R′ are the same or different and are any organic group capable of bonding to a carbon.

Examples of non-rigid rod diamines include: 4,4′-diaminodiphenyl ether (“ODA”), 2,2-bis-(4-aminophenyl)propane, 1,3-diaminobenzene (MPD), 4,4′-diaminobenzophenone, 4,4′-diaminodiphenylmethane, 4,4′-diaminodiphenyl sulfide, 4,4′-diaminodiphenyl sulfone, 3,3′-diaminodiphenyl sulfone, bis-(4-(4-aminophenoxy)phenyl sulfone (BAPS), 4,4′-bis-(aminophenoxy)biphenyl (BAPB), 3,4′-diaminodiphenyl ether, 4,4′-diaminobenzophenone, 4,4′-isopropylidenedianiline, 2,2′-bis-(3-aminophenyl)propane, N,N-bis-(4-aminophenyl)-n-butylamine, N,N-bis-(4-aminophenyl)methylamine, 3,4′-diamino benzanilide, 4-aminophenyl-3-aminobenzoate, N,N-bis-(4-aminophenyl)aniline, 2,4-diaminotoluene, 2,6-diaminotoluene, 2,4-diamine-5-chlorotoluene, 2,4-diamino-6-chlorotoluene, 2,4-bis-(beta-amino-t-butyl)toluene, bis-(p-beta-amino-t-butyl phenyl)ether, m-xylylene diamine, p-xylylene diamine. 1,2-bis-(4-aminophenoxy)benzene, 1,3-bis-(4-aminophenoxy)benzene, 1,2-bis-(3-aminophenoxy)benzene, 1,3-bis-(3-aminophenoxy)benzene, 1-(4-aminophenoxy)-3-(3-aminophenoxy)benzene, 1,4-bis-(4-aminophenoxy)benzene, 1,4-bis-(3-aminophenoxy)benzene, 1-(4-aminophenoxy)-4-(3-aminophenoxy)benzene, 2,2-bis-(4-[4-aminophenoxy]phenyl)propane (BAPP), 2,2′-bis-(4-aminophenyl)-hexafluoro propane (6F diamine), 2,2′-bis-(4-phenoxy aniline) isopropylidene, 4,4′-diamino-2,2′-trifluoromethyl diphenyloxide, 3,3′-diamino-5,5′-trifluoromethyl diphenyloxide, 4,4′-trifluoromethyl-2,2′-diaminobiphenyl, 2,4,6-trimethyl-1,3-diaminobenzene, 4,4′-oxy-bis-[2-trifluoromethyl)benzene amine] (1,2,4-OBABTF), 4,4′-oxy-bis-[3-trifluoromethyl)benzene amine], 4,4′-thio-bis-[(2-trifluoromethyl)benzene-amine], 4,4′-thiobis[(3-trifluoromethyl)benzene amine], 4,4′-sulfoxyl-bis-[(2-trifluoromethyl)benzene amine, 4,4′-sulfoxy]-bis-[(3-trifluoromethyl)benzene amine], and 4,4′-keto-bis-[(2-trifluoromethyl)benzene amine].

Examples of non-rigid rod aromatic dianhydrides include, 2,2′,3,3′-benzophenone tetracarboxylic dianhydride, 2,3,3′,4′-benzophenone tetracarboxylic dianhydride, 3,3′,4,4′-benzophenone tetracarboxylic dianhydride (BTDA), 2,2′,3,3′-biphenyl tetracarboxylic dianhydride, 2,3,3′,4′-biphenyl tetracarboxylic dianhydride, 4,4′-thio-diphthalic anhydride, bis(3,4-dicarboxyphenyl)sulfone dianhydride (DSDA), bis(3,4-dicarboxyphenyl)sulfoxide dianhydride, 4,4′-oxydiphthalic anhydride (ODPA), bis(3,4-dicarboxyphenyl)thio ether dianhydride, bisphenol A dianhydride (BPADA), bisphenol S dianhydride, 2,2-bis-(3,4-dicarboxyphenyl) 1,1,1,3,3,3,-hexafluoropropane dianhydride (6FDA), 5,5-[2,2,2]-trifluoro-1-(trifluoromethyl)ethylidene, bis-1,3-isobenzofurandione, bis(3,4-dicarboxyphenyl)methane dianhydride, and 2,2-bis(3,4-dicarboxyphenyl)propane dianhydride.

In some embodiments, non-rigid rod monomers may be considered for up to (and including) 15 mole percent of the aromatic dianhydride and/or up to (and including) 15 mole percent of the aromatic diamine, depending upon desired properties for any particular application of the present invention.

Polyimide films of the present disclosure can be made by methods well known in the art. In some embodiments, the polyimide film can be produced by combining the above monomers together with a solvent to form a polyamic acid (also called a polyamide acid solution). The dianhydride and diamine components are typically combined in a molar ratio of aromatic dianhydride component to aromatic diamine component of from 0.90 to 1.10. Molecular weight can be adjusted by adjusting the molar ratio of the dianhydride and diamine components.

Chemical or thermal conversion can be used in the practice of the present disclosure. In instances where chemical conversion is used, a polyamic acid casting solution is derived from the polyamic acid solution. In one embodiment, the polyamic acid casting solution comprises the polyamic acid solution combined with conversion chemicals, such as: (i) one or more dehydrating agents, such as, aliphatic acid anhydrides (acetic anhydride, etc.) and aromatic acid anhydrides; and (ii) one or more catalysts, such as, aliphatic tertiary amines (triethylamine, etc.), aromatic tertiary amines (dimethylaniline, etc) and heterocyclic tertiary amines (pyridine, picoline, isoquinoilne, etc). The anhydride dehydrating material is often used in a molar excess of the amount of amide acid groups in the copolyamic acid. The amount of acetic anhydride used is typically about 2.0-3.0 moles per equivalent of amide acid. Generally, a comparable amount of tertiary amine catalyst is used.

In one embodiment, the polyamic acid is dissolved in an organic solvent at a concentration from about 5 weight percent up to and including 90 weight percent. In one embodiment, the polyamic acid is dissolved in an organic solvent at a concentration of about 5, 10, 15, 20, 25, 30, 35, 40, 45, 50, 55, 60, 65, 70, 75, 80, 85, or 90 weight percent. Examples of suitable solvents include: sulfoxide solvents (dimethyl sulfoxide, diethyl sulfoxide, etc.), formamide solvents (N,N-dimethylformamide, N,N-diethylformamide, etc.), acetamide solvents (N,N-dimethylacetamide, N,N-diethylacetamide, etc.), pyrrolidone solvents (N-methyl-2-pyrrolidone, N-vinyl-2-pyrrolidone, etc.), phenol solvents (phenol, o-, m- or p-cresol, xylenol, halogenated phenols, catechol, etc.), hexamethylphosphoramide and gamma-butyrolactone. It is desirable to use one of these solvents or mixtures thereof. It is also possible to use combinations of these solvents with aromatic hydrocarbons such as xylene and toluene, or ether containing solvents like diglyme, propylene glycol methyl ether, propylene glycol, methyl ether acetate, tetrahydrofuran, and the like.

The filler (dispersion or nanocolloid thereof) can be added at several points in the polyimide film preparation. In one embodiment, the nanocolloid is incorporated into a prepolymer to yield a Brookfield solution viscosity in the range of about 50-100 poise at 25° C. “Prepolymer” is intended to mean a lower molecular weight polymer, typically made with a slight stoichiometric excess (about 2%) of diamine monomer (or excess dianhydride monomer). Increasing the molecular weight (and solution viscosity) of the prepolymer can be accomplished by adding incremental amounts of additional dianhydride (or additional diamine, in the case where the dianhydride monomer is originally in excess in the prepolymer) in order to approach a 1:1 stoichiometric ratio of dianhydride to diamine.

In an alternative embodiment, the nanocolloid can be combined with the monomers directly, and in this case, polymerization occurs with the nanocolloid present during the reaction. The monomers may have an excess of either monomer (diamine or dianhydride) during this “in situ” polymerization. The monomers may also be added in a 1:1 ratio. In the case where the monomers are added with either the amine (case i) or the dianhydride (case ii) in excess, increasing the molecular weight (and solution viscosity) can be accomplished, if necessary, by adding incremental amounts of additional dianhydride (case i) or diamine (case ii) to approach the 1:1 stoichiometric ratio of dianhydride to amine.

The polyamic acid casting solution can then be cast or applied onto a support, such as an endless belt or rotating drum, to give a film. Next, the solvent-containing film can be converted into a self-supporting film by baking at an appropriate temperature (thermal curing) together with conversion chemical reactants (chemical curing). The film can then be separated from the support, oriented such as by tentering, with continued thermal and chemical curing to provide a polyimide film.

An alkoxy silane coupling agent can be added during the process by pretreating the nanocolloid prior to formulation. Alkoxysilane coupling agents can also be added during the “in situ” polymerization by combining the nanocolloids and monomers with the alkoxysilane.

In some cases, the dianhydride can be contacted with the nanocolloid. While not intending to be bound to any particular theory or hypothesis, it is believed such contact between the dianhydride and the nanocolloid can functionalize the nanocolloid with the dianhydride prior to further reaction with the monomers or prepolymer. Ultimately, a filled polyamic acid composition is generally cast into a film, which is subjected to drying and curing (chemical and/or thermal curing) to form a filled polyimide free-standing or non free-standing film. Any conventional or non-conventional method of manufacturing filled polyimide films can be used in accordance with the present disclosure. The manufacture of filled polyimide films in general is well known and need not be further described here. In one embodiment, the polyimide used in an assembly of the present disclosure has a high glass transition temperature (Tg) of greater than 300, 310, 320, 330, 340, 350, 360, 370 380, 390 or 400° C. A high Tg generally helps maintain mechanical properties, such as storage modulus, at high temperatures.

In some embodiments, the crystallinity and amount of crosslinking of the polyimide film can aid in storage modulus retention. In one embodiment, the polyimide film storage modulus (as measured by dynamic mechanical analysis, DMA) at 480° C. is at least: 400, 450, 500, 550, 600, 650, 700, 750, 800, 850, 900, 950, 1000, 1100, 1200, 1300, 1400, 1500, 1600, 1800, 2000, 2200, 2400, 2600, 2800, 3000, 3500, 4000, 4500, or 5000 MPa.

In some embodiments, the polyimide film used in an assembly of the present disclosure has an isothermal weight loss of less than 2, 1.5, 1, 0.75, 0.5 or 0.3 percent at 500° C. over about 30 minutes in an inert environment, such as, in a vacuum or under nitrogen or other inert gas. Polyimides used in the assemblies of the present disclosure have high dielectric strength, generally higher than many common inorganic insulators. In some embodiments, polyimides used in the assemblies of the present disclosure have a breakdown voltage equal to or greater than 10 V/micrometer.

The polyimide film can further comprise any one of a number of additives, such as processing aids (e.g., oligomers), antioxidants, light stabilizers, flame retardant additives, anti-static agents, heat stabilizers, ultraviolet absorbing agents, fillers or various reinforcing agents.

In some embodiments, electrically insulating fillers may be added to modify the electrical properties of the polyimide film. In some embodiments, it is important that the polyimide film be free of pinholes or other defects (foreign particles, gels, filler agglomerates or other contaminates) that could adversely impact the electrical integrity and dielectric strength of the polyimide film, and this can generally be addressed by filtering. Such filtering can be done at any stage of the film manufacture, such as, filtering solvated filler before or after it is added to one or more monomers and/or filtering the polyamic acid, particularly when the polyamic acid is at low viscosity, or otherwise, filtering at any step in the manufacturing process that allows for filtering. In one embodiment, such filtering is conducted at the minimum suitable filter pore size or at a level just above the largest dimension of the selected filler material.

A single layer polyimide film can be made thicker in an attempt to decrease the effect of defects caused by unwanted (or undesirably large) discontinuous phase material within the film. Alternatively, multiple layers of polyimide may be used to diminish the harm of any particular defect (unwanted discontinuous phase material of a size capable of harming desired properties) in any particular layer, and generally speaking, such multilayers will have fewer defects in performance compared to a single polyimide layer of the same thickness. Using multiple layers of polyimide films can diminish or eliminate the occurrence of defects that may span the total thickness of the film, because the likelihood of having defects that overlap in each of the individual layers tends to be extremely small. Therefore, a defect in any one of the layers is much less likely to cause an electrical or other type failure through the entire thickness of the film. In some embodiments, the polyimide film comprises two or more layers. In some embodiments, the polyimide layers are the same. In some embodiments, the polyimide layers are different. In some embodiments, the polyimide layers independently may comprise a thermally stable filler, reinforcing fabric, inorganic paper, sheet, scrim or combinations thereof. Optionally, 0-55 weight percent of the polyimide film also includes other ingredients to modify properties as desired or required for any particular application.

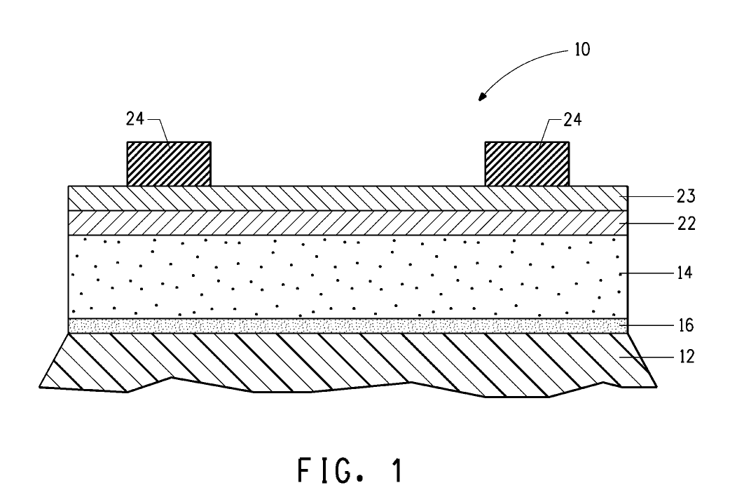

Referring now to FIG. 1, an embodiment of the present disclosure is illustrated as a thin-film solar cell, indicated generally at 10. The thin-film solar cell 10 includes a flexible polyimide film substrate 12 containing nanoscopic inorganic oxide filler as described and discussed above. A bottom electrode 16 (comprising molybdenum, for example) is applied onto the flexible polyimide film substrate 12, such as, by sputtering, evaporation deposition or the like. A semiconductor light absorber layer 14 (comprising Cu(In,Ga)Se₂, for example) is deposited over the bottom electrode 16. The deposition of the semiconductor light absorber layer 14 onto the bottom electrode 16 and the flexible polyimide film substrate 12 can be by any of a variety of conventional or non-conventional techniques including, but not limited to, casting, laminating, co evaporation, sputtering, physical vapor deposition, chemical vapor deposition, and the like. Deposition processes for semiconductor light absorber layer 14 are well known and need not be further described here (examples of such deposition processes are discussed and described in U.S. Pat. No. 5,436,204 and U.S. Pat. No. 5,441,897).

An optional adhesion layer or adhesion promoter (not shown) can be used to increase adhesion between any of the above described layers. In one embodiment, the flexible polyimide film substrate 12 is thin and flexible, i.e., approximately 8 microns to approximately 150 microns, in order that the thin-film solar cell 10 is lightweight, or the flexible polyimide film substrate 12 can be thick and rigid to improve handling of the thin-film solar cell 10.

To complete the construction of the thin-film solar cell 10 in this particular embodiment, additional optional layers can be applied. For example, the CIGS light absorber layer 14 can be paired (e.g., covered) with a II/VI film 22 to form a photoactive heterojunction. In some embodiments, the II/VI film 22 is constructed from cadmium sulfide (CdS). Alternatively, the II/VI films 22 can be constructed from other materials including, but not limited to, cadmium zinc sulfide (CdZnS) and/or zinc selenide (ZnSe) is also within the scope of the present disclosure.

A transparent conducting oxide (TCO) layer 23 for collection of current is applied to the II/VI film. Preferably, the transparent conducting oxide layer 23 is constructed from zinc oxide (ZnO), although constructing the transparent conducting oxide (“TCO”) layer 23 from other materials is also within the scope of the present disclosure.

A suitable grid contact 24 or other suitable collector is deposited on the upper surface of the TCO layer 23 when forming a stand-alone thin-film solar cell 10. The grid contact 24 can be formed from various materials but should have high electrical conductivity and form a good ohmic contact with the underlying TCO layer 23. In some embodiments, the grid contact 24 is constructed from a metal material, although constructing the grid contact 24 from other materials including, but not limited to, aluminum, indium, chromium, or molybdenum, with an additional conductive metal overlayment, such as copper, silver, or nickel is within the scope of the present disclosure.

In some embodiments, one or more anti-reflective coatings (not shown) can be applied to the exposed surfaces of the grid contact 24 and the exposed surfaces of transparent conducting oxide layer 23 that are not in contact with the grid contacts. In another embodiment, an anti-reflective coating can be applied to only the exposed surfaces of transparent conducting oxide layer 23 that are not in contact with the grid contacts. The anti-reflective coating improves the collection of incident light by the thin-film solar cell 10. As understood by a person skilled in the art, any suitable anti-reflective coating is within the scope of the present disclosure.

The invention will be further described in the following examples, which are not intended to limit the scope of the invention described in the claims.

### EXAMPLES

### Example 1

Molybdenum layer (˜500 nm)+Nanosilica Filled Polyimide (PPD/BPDA) Layer, where the PPD:BPDA mole ratio was 0.98:1, and where the nanosilica loading in the polyimide was 8.25 wt % (0.05 volume fraction nanosilica in the polyimide).

In a 500 ml round bottom flask, a mixture of the following reagents was added: 0.33 g of aminopropyltrimethoxysilane (Aldrich, St. Louis, Mo., 92%), 7.98 g of DMAC-ST (Nissan Chemicals, Houston, Tex., 20.5 wt nanosilica in DMAC) and 5.299 g of PPD (paraphenylenediame), 14.71 g of BPDA (3,3′,4,4′-Biphenyltetracarboxylic dianhydride) and an 100 additional ml of anhydrous DMAC (dimethylacetamide, Aldrich 271012, Allenton, Pa.). The reagents were stirred at room temperature for 24 hours. The final viscosity was approximately 233 poise as measured on a Brookfield DV-E viscometer with a #5 spindle. PPD:BPDA mole ratio was 0.98:1.

The formulation was cast using a 25 mil doctor blade onto a surface of a glass plate to form a 3″×4″ film. The glass was pretreated with a release agent to facilitate removal of the film from the glass surface. The film was allowed to dry on a hot plate at 80° C. for 20 minutes. The film was subsequently lifted off the surface, and mounted on a 3″×4″ pin frame.

After further drying at room temperature under vacuum for 12 hours, the mounted film was placed in a furnace (Thermolyne, F6000 box furnace). The furnace was purged with nitrogen and heated according to the following temperature protocol:

| | |
|---|---|
| 125° C. | (30 min) |
| 125° C. to 350° C. | (ramp at 4° C./min) |
| 350° C. | (30 min) |
| 350° C. to 450° C. | (ramp at 5° C./min) |
| 450° C. | (20 min) |
| 450° C. to 40° C. | (cooling at 8° C./min) |

A molybdenum layer (about 500 nm thick) was sputtered onto both sides of the polyimide layer. Specifically, a Denton Discovery 20LL sputtering chamber was used for the deposition of molybdenum onto both sides of the polyimide film described above. The device was equipped with three 3″ Angstrom Sciences sputtering guns and a 3″×¼″ molybdenum (K. J. Lesker, 2×S.C.I., 99.95% & 99.99%) target. Ultra high purity grade Ar gas (GT&S Inc.) was used for the sputtering experiments.

The film samples were attached to a platter using Kapton® tape then inserted into a load lock (LL) chamber. The LL chamber was pumped down to a suitable pressure, and subsequently an isolation valve was opened and the sample was transferred into the main chamber. It was rotated while held in a horizontal orientation during the operation.

All sputter guns were positioned six inches distance from the samples, and approximately 3 inches from the outside circumference. In addition, the sputter gun face was at an angle of 20 degrees from vertical and aimed toward the axis of the sample platter.

20 sccm (standard cubic centimeters per minute) of Argon was introduced and a pressure of 5 millitorr was established. The power supplies were started with a 150 watt set point and allowed to establish plasma and stabilize for approximately one half minute after which a shutter covering the target face was opened and a timer started.

At the end of the required time period the power supply, argon flow, and pressure controllers were shut off, the rotation was stopped and the platter was withdrawn into the LL chamber. The isolation valve was closed. After the LL chamber was vented with nitrogen gas, the samples were removed from the Denton 20LL.

Base pressure of the system was approximately 5×10⁻⁷ torr (or lower) before and after deposition.

Following the deposition of the molybdenum layer, the material was examined in cross section by scanning electron microscopy. A small piece of film (approximately 1 cm×1 cm) was cut for this analysis. The sample was freeze “fractured”. The sample and a fresh single edged razor blade were concurrently immersed in liquid nitrogen for 20 to 30 seconds. The sample and razor were withdrawn from the liquid nitrogen and the razor, in a guillotine motion, was using to initiate a cryogenic cut or fracture to expose the material in cross section. The sample was allowed to warm to room temperature and was trimmed to less than or equal to 1 mm high before mounting on a sample mount (5 mm (w)×7 mm (I)) using Duco brand cement, and coated with 1 nanometer (“nm”) of osmium (using plasma reaction of OsO₄) to enable higher resolution by the SEM technique. The material was placed in a Hitachi S5000SP high resolution FE-SEM at 1 keV accelerating voltage.

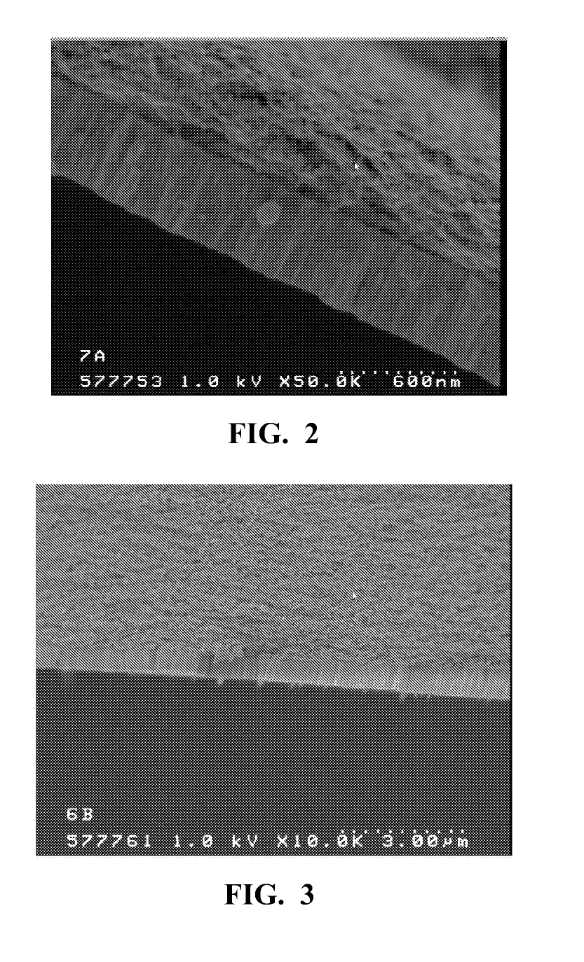

Scanning electron micrographs were taken showing the molybdenum layer well adhered to the polyimide composite. A representative micrograph is illustrated in FIG. 2, where an approximately 500 nm Molybdenum layer is shown (having a columnar microstructure) and is adhered to a polyimide surface. The polyimide film is about 2 mils (approximately 50 microns) thick and has peeled away from itself (cohesively failed), but there is no adhesive failure at the polyimide/Molybdenum interface.

### Example 2

Molybdenum layer (˜500 nm)+Nanosilica Filled Polyimide (PPD/BPDA) Layer, where the PPD:BPDA mole ratio was 0.98:1, and where the nanosilica loading in the polyimide was 29 wt % (0.20 volume fraction nanosilica in the polyimide).

The same procedure as described in example 1 was used, with the following differences.

In a 500 ml round bottom flask, a mixture was added in the following order:

93.865 grams of anhydrous DMAC solvent was added, followed by 14.480 g of BPDA. 36.224 grams of nanosilica was then added, and the mixture was allowed to stir for about 30 minutes. The nanosilica colloid had been previously stored over dried molecular sieves to remove any residual water.

After thirty minutes, 5.431 grams of PPD was added slowly to the mixture. The temperature of the reaction was not allowed to rise above about 40° C.

Scanning electron micrographs were taken showing the molybdenum layer well adhered to the polyimide composite. A representative micrograph is illustrated in FIG. 3, where an approximately 500 nm Molybdenum layer a columnar microstructure, is adhered to a polyimide layer. The polyimide layer (2 mils in thickness or approximately 50 microns) has peeled away from itself. There is no failure at the polyimide/Molybdenum interface.

### Example 3

Molybdenum layer (˜500 nm)+Nanosilica Filled Polyimide (PPD/BPDA) Layer, where the PPD:BPDA mole ratio was 0.98:1, and where the nanosilica loading in the polyimide was 15.43 wt % (0.10 volume fraction nanosilica in the polyimide).

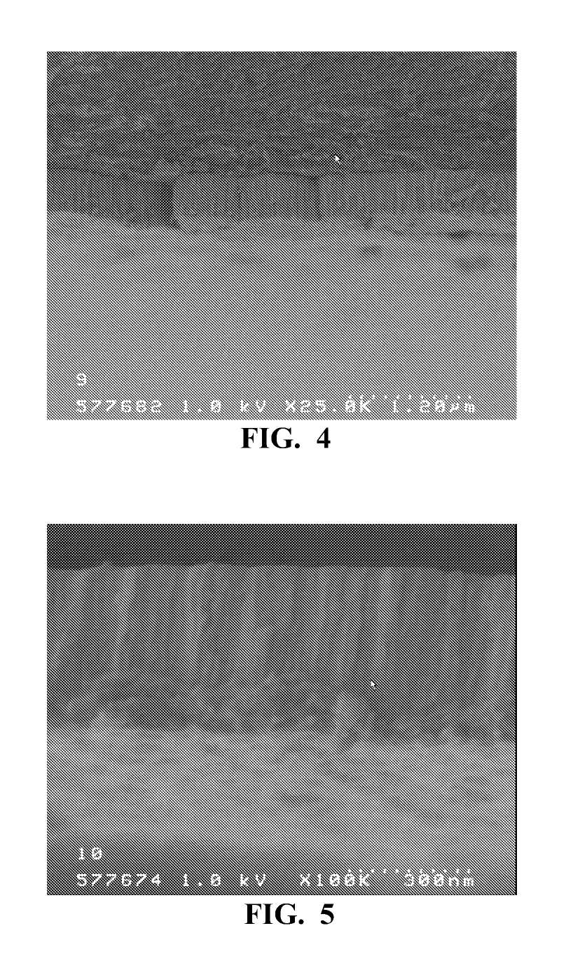

The same procedure as was described in example 2 was followed, with the following differences. 108.397 g of DMAC, 16.904 g of BPDA, 18.61 g of nanosilica colloid, and 6.089 g of PPD were used. Scanning electron micrographs were taken showing the molybdenum layer well adhered to the polyimide composite. A representative micrograph is illustrated in FIG. 4, where a ˜500 nm Molybdenum layer is adhered to a polyimide layer. There is no failure at the polyimide/molybdenum interface.

### Example 4

Molybdenum layer (˜500 nm)+Nanosilica Filled Polyimide (PPD/BPDA) Layer, where the PPD:BPDA mole ratio was 0.98:1, and where the nanosilica loading in the polyimide was 29 wt % (0.20 volume fraction nanosilica in the polyimide).

The same procedure as was described in example 2 was followed, with the following differences. 93.844 g of anhydrous DMAC, 14.635 g of BPDA, 36.25 g of nanosilica colloid, and 5.272 g of PPD were used. Scanning electron micrographs were taken showing the molybdenum layer well adhered to the polyimide composite. A representative micrograph is illustrated in FIG. 5, where a ˜500 nm Molybdenum layer, a columnar microstructure, is adhered to a polyimide layer. The polyimide layer (originally 2 mils thick or approximately 50 microns) has peeled away from itself. There is no failure at the polyimide/Molybdenum interface.

### Comparative Example A

Unfilled Polyimide Layer+Molybdenum Layer

The procedure described in Example 1 was used, with the following difference. BPDA/PPD “prepolymer” (69.3 g of a 17.5 wt % solution in anhydrous DMAC) was used. “Prepolymer” refers to a low molecular weight polymer made by a slight stoichiometric excess of PPD monomer (about 2%; BPDA:PPD=0.98:1).

In a separate container, a 6 wt % solution of pyromellitic anhydride (PMDA) was prepared by combining 0.9 g of PMDA (Aldrich 412287, Allentown, Pa.) and 15 ml of DMAC.

Increasing molecular weight was accomplished by adding small incremental amounts of additional dianhydride in order to approach stoichiometric equivalent of dianhydride to diamine. Hence, the PMDA solution was slowly added to the prepolymer slurry to achieve a final viscosity of 993 poise. The formulation was stored overnight at 0° C. to allow it to degas.

The formulation was cast using a 25 mil doctor blade onto a surface of a glass plate to form a 3″×4″ film. The glass was pretreated with a release agent to facilitate removal of the film from the glass surface. The film was allowed to dry on a hot plate at 80° C. for 20 minutes. The film was subsequently lifted off the surface, and mounted on a 3″×4″ pin frame.

After further drying at room temperature under vacuum for 12 hours, the mounted film was placed in a furnace (Thermolyne, F6000 box furnace). The furnace was purged with nitrogen and heated according to the following temperature protocol:

| | |
|---|---|
| 125° C. | (30 min) |
| 125° C. to 350° C. | (ramp at 4° C./min) |
| 350° C. | (30 min) |
| 350° C. to 450° C. | (ramp at 5° C./min) |
| 450° C. | (20 min) |
| 450° C. to 40° C. | (cooling at 8° C./min) |

A molybdenum layer (about 500 nm thick) was sputtered onto both sides of the polyimide layer using the same procedures described in Example 1.

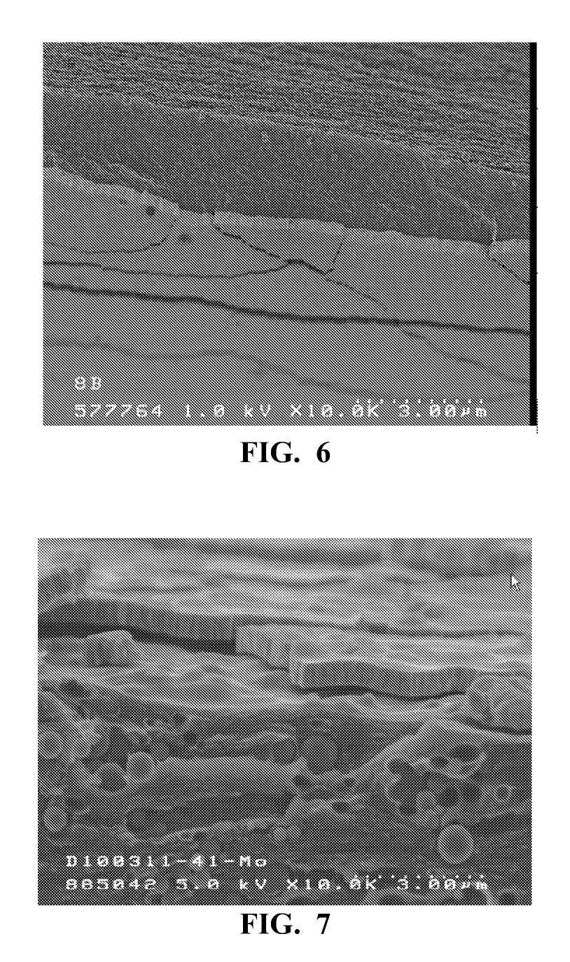

Following the deposition of the molybdenum layer, the material was examined in cross section by scanning electron microscopy. A representative micrograph is illustrated at FIG. 6. The cross sectional SEM image indicates that the Molybdenum layer was not as strongly adhered as the Molybdenum layers in Examples 1-4. Comparative Example A showed evidence of the molybdenum layer cracking and delaminating from the polyimide layer.

### Comparative Example B

Molybdenum layer (˜500 nm)+polyimide (BPDA/PPD) layer comprising silica filler (average size, 0.4-0.6 micron microspheres), where the silica loading in the polyimide was 15.43 wt % (0.10 volume fraction nanosilica in the polyimide).

The procedure described in Comparative A was used, with the following differences. BPDA/PPD prepolymer (70 g of a 17.5 wt % solution in anhydrous DMAC) was combined with 5.2 g of Admatechs' SE-02 silica microspheres (Admatechs's, Miyoshi-chow, Nishikamo-gun, Aichi, Japan).

In a separate container, an 8 wt % solution of pyromellitic anhydride (PMDA) was prepared by combining 1.2 g of PMDA (Aldrich 412287, Allentown, Pa.) and 15 ml of DMAC.

The PMDA solution was slowly added to the BPDA/PPD prepolymer to achieve a final viscosity of 200 poise. The formulation was stored overnight at 0° C. to allow it to degas prior to casting and imidization, according to the procedures described in Example 1.

A molybdenum layer (about 500 nm thick) was sputtered onto both sides of the polyimide layer using the procedures described in Example 1.

Following the deposition of the molybdenum layer, the material was examined in cross section by scanning electron microscopy. A representative micrograph is illustrated at FIG. 7. The cross sectional SEM image indicates that the Molybdenum layer 10 is not as strongly adhered as the molybdenum layers described in Examples 1-4. The molybdenum layer had cracking and delamination from the polymide layer. The silica filler spheres within the polyimide layer are greater than 0.1 microns (average size 0.4-0.6 microns) and do not provide the improved bonding at the molybdenum/polyimide interface as was seen in Examples 1-4, where the filler was much smaller (average diameter <100 nm in all dimensions).

### Example 5

Polyimide film+nanosilica (no Molybdenum layer), where the nanosilica loading in the polyimide was 8.25 wt % (0.05 volume fraction nanosilica in the polyimide).

The same procedure as described in Example 1 was used, except that the molybdenum layer was not applied on top of the substrate.

Thermomechanical measurements were performed on the film, as shown in Table 1.

A DMA (TA Instruments Q800 model) was used for a creep/recovery study of film specimens in tension and customized controlled force mode. A pressed film of 6-6.4 mm width, 0.03-0.05 mm thickness and 10 mm length was clamped between stationary jaws and movable jaws in 3 in-lb torque force. The static force in the length direction was 0.005N. The film was heated to 460° C. at 20° C./min rate and held at 460° C. for 150 min. The creep program was set at 2 MPa for 20 min, followed by recovery for 30 min with no additional force other than the initial static force of (0.005N). The creep/recovery program was repeated for 4 MPa and 8 MPa and the same time intervals as that for 2 MPa.

In Table 1 below are tabulated the strain and the recovery following the cycle at 8 MPa (more precisely, the maximum stress being from about 7.4 to 8.0 MPa). The elongation is converted to a unit-less equivalent strain by dividing the elongation by the starting film length. The strain at 8 MPa (more precisely, the maximum stress being from about 7.4 to 8.0 MPa) and 460° C. is tabulated, “emax”. The term “e max” is the dimensionless strain which is corrected for any changes in the film due to decomposition and solvent loss (as extrapolated from the stress free slope) at the end of the 8 MPa cycle (more precisely, the maximum stress being from about 7.4 to 8.0 MPa). The term “e rec” is the strain recovery immediately following the 8 MPa cycle (more precisely, the maximum stress being from about 7.4 to 8.0 MPa), but at no additional applied force (other than the initial static force of 0.005 N), which is a measure of the recovery of the material, corrected for any changes in film due to decomposition and solvent loss as measured by the stress free slope). The parameter, labeled “stress free slope”, is also tabulated in units of dimensionless strain/min and is the change in strain when the initial static force of 0.005 N is applied to the sample after the initial application of the 8 Mpa stress (more precisely, the maximum stress being from about 7.4 to 8.0 MPa). This slope is calculated based on the dimensional change in the film (“stress free strain”) over the course of 30 min following the application of the 8 MPa stress cycle (more precisely, the maximum stress being from about 7.4 to 8.0 MPa). Typically the stress free slope is negative. However, the stress free slope value is provided as an absolute value and hence is always a positive number.

The third column, e plast, describes the plastic flow, and is a direct measure of high temperature creep, and is the difference between e max and e rec.

In general, a material which exhibits the lowest possible strain (e max), the lowest amount of stress plastic flow (e plast) and a low value of the stress free slope is desirable.

### Example 6

Polyimide film+nanosilica(no Molybdenum layer)

The same procedure as described in Example 2 was used, except that the molybdenum layer was not applied on top of the substrate. The thermo-mechanical performance is summarized in Table 1.

### Example 7

Polyimide film+nanosilica(no Molybdenum layer)

The same procedure as described in Example 3 was used, except that the molybdenum layer was not applied on top of the substrate. The thermo-mechanical performance is summarized in Table 1.

### Example 8

Polyimide film+nanosilica(no Molybdenum layer)

The same procedure as described in Example 4 was used, except that the molybdenum layer was not applied on top of the substrate. The thermo mechanical performance is summarized in Table 1.

### Comparative Example C

BPDA/PPD prepolymer (69.3 g of a 17.5 wt % solution in anhydrous DMAC) was used. In a separate container, a 6 wt % solution of pyromellitic anhydride (PMDA) was prepared by combining 0.9 g of PMDA (Aldrich 412287, Allentown, Pa.) and 15 ml of DMAC.

The PMDA solution was slowly added to the prepolymer slurry to achieve a final viscosity of 993 poise. The formulation was stored overnight at 0° C. to allow it to degas.

The formulation was cast using a 25 mil doctor blade onto a surface of a glass plate to form a 3″×4″ film. The glass was pretreated with a release agent to facilitate removal of the film from the glass surface. The film was allowed to dry on a hot plate at 80° C. for 20 minutes. The film was subsequently lifted off the surface, and mounted on a 3″×4″ pin frame.

After further drying at room temperature under vacuum for 12 hours, the mounted film was placed in a furnace (Thermolyne, F6000 box furnace). The furnace was purged with nitrogen and heated according to the following temperature protocol:

| | |
|---|---|
| 125° C. | (30 min) |
| 125° C. to 350° C. | (ramp at 4° C./min) |
| 350° C. | (30 min) |
| 350° C. to 450° C. | (ramp at 5° C./min) |
| 450° C. | (20 min) |
| 450° C. to 40° C. | (cooling at 8° C./min) |

The thermo mechanical performance is summarized in Table 1.

### Example 9

Polyimide film+nanosilica(no Molybdenum layer),

The procedure described in Comparative Example A was used, with the following differences. In this example, a molybdenum layer was not sputtered onto the polyimide composite and the nanosilica loading in the polyimide was 20 wt % (0.134 volume fraction nanosilica in the polyimide).

158.84 grams of BPDA/PPD “prepolymer” was used. In a separate container, 30.897 grams if Nissan DMAC-ST colloid was contacted with 0.26 grams of pyromellitic anhydride under a nitrogen blanket. The colloid with PMDA was allowed to stir for sixty minutes.

The BPDA/PPD prepolymer was then combined with silica colloid containing PMDA, and allowed to stir for four hours.

The viscosity of this formulation was adjusted using a 6 wt solution of pyromellitic dianhydride to a final viscosity of approximately 190 poise.

The thermo mechanical performance is summarized in Table 1.

TABLE 1

| | | | | Plastic | Absolute |
|---|---|---|---|---|---|
| | | e max | | deformation | Value |
| | Applied | (strain at | | ((eplast) = e | Stress |
| | Stress | applied | | max − e | Free Slope |
| Sample No. | (MPA)* | stress) | e rec | rec)) | (/min) |
| 5 | 7.48 | 1.01E−02 | 8.84E−03 | 1.22E−03 | 1.59E−05 |
| 6 | 8.01 | 5.04E−03 | 4.45E−03 | 5.85E−04 | 8.84E−06 |
| 7 | 8.01 | 6.75E−03 | 6.15E−03 | 5.98E−04 | 7.01E−06 |
| 8 | 8.03 | 9.53E−03 | 8.21E−03 | 1.33E−03 | 1.29E−05 |
| Comparative | 7.52 | 1.50E−02 | 1.40E−02 | 9.52E−04 | 9.98E−06 |
| Example C | | | | | |
| 9 | 8.02 | 8.25E−03 | 7.25E−03 | 9.94E−04 | 1.24E−05 |

In particular, the strain at 8 MPa (e max) is improved, by nearly a factor of two, compared to the control film, comparative example C.

Table 2 which tabulates the equivalent volume fraction of nanoscopic silica and weight percentage of nanoscopic silica in Examples 1-9.

TABLE 2

| | equivalent volume | |
|---|---|---|
| | fraction, using 2.33 g/cc | |
| | for SiO2 and | |
| | 1.42 g/cc for | wt % nanosilica |
| Example | polyimide | in polyimide |
| Example 1 (with Mo) | 0.05 | 8.25 |
| and | | |
| Example 5 (without Mo) | | |
| Example 2 (with Mo) | 0.20 | 29.09 |
| and | | |
| Example 6 (without Mo) | | |
| Example 3 (with Mo), | 0.10 | 15.43 |
| comparative B and | | |
| Example 7 (without Mo) | | |
| Example 4 (with Mo) | 0.20 | 29.11 |
| and | | |
| Example 8 (without Mo) | | |
| Example 9 (without Mo) | 0.134 | 20 |

Note that not all of the activities described above in the general description or the examples are required, that a portion of a specific activity may not be required, and that further activities may be performed in addition to those described. Still further, the order in which each of the activities are listed are not necessarily the order in which they are performed. After reading this specification, skilled artisans will be capable of determining what activities can be used for their specific needs or desires.

In the foregoing specification, the invention has been described with reference to specific embodiments. However, one of ordinary skill in the art appreciates that various modifications and changes can be made without departing from the scope of the invention as set forth in the claims below. All features disclosed in this specification may be replaced by alternative features serving the same, equivalent or similar purpose. Accordingly, the specification and figures are to be regarded in an illustrative rather than a restrictive sense and all such modifications are intended to be included within the scope of the invention.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims.

What is claimed is:

1. An assembly comprising:
A) a polyimide film comprising:
a) a polyimide in an amount from 40 to 95 weight percent of the polyimide film, the polyimide being derived from:
i) at least one aromatic dianhydride, at least 85 mole percent of said aromatic dianhydride being a rigid rod type dianhydride, and
ii) at least one aromatic diamine, at least 85 mole percent of said aromatic diamine being a rigid rod type diamine; and
b) a filler that:
i) has an average diameter of less than 100 nanometers in all dimensions; and
ii) is present in an amount from 5 to 60 weight percent of the total weight of the polyimide film, the polyimide film having a thickness from 8 to 150 microns,
B) a light absorber layer, and
C) an electrode supported by said polyimide film, said electrode being between the light absorber layer and the polyimide film and said electrode being in electrical communication with the light absorber layer.

2. An assembly in accordance with claim 1, wherein the light absorber layer is a CIGS/CIS light absorber layer.

3. An assembly in accordance with claim 1, wherein the assembly further comprises a plurality of monolithically integrated CIGS/CIS photovoltaic cells.

4. An assembly in accordance with claim 1, wherein the filler is smaller than 60 nm in all dimensions, and the assembly further comprises a plurality of monolithically integrated CIGS/CIS photovoltaic cells.

5. An assembly in accordance with claim 1, wherein the filler is an inorganic oxide and the assembly further comprises a plurality of monolithically integrated CIGS/CIS photovoltaic cells.

6. An assembly in accordance with claim 5, wherein the filler is silicon oxide.

7. An assembly in accordance with claim 1, wherein:
a) the rigid rod type dianhydride is selected from a group consisting of 3,3′,4,4′-biphenyl tetracarboxylic dianhydride (BPDA), pyromellitic dianhydride (PMDA), and mixtures thereof; and
b) the rigid rod type diamine is selected from 1,4-diaminobenzene (PPD), 4,4′-diaminobiphenyl, 2,2′-bis(trifluoromethyl)benzidene (TFMB), 1,5-naphthalenediamine, 1,4-naphthalenediamine, and mixtures thereof.

8. An assembly in accordance with claim 1, wherein the polyimide film comprises a coupling agent, a dispersant or a combination thereof.

9. An assembly in accordance with claim 1, wherein the filler is an inorganic oxide, and the polyimide film has the following properties: (i) a Tg greater than 300° C., (ii) a dielectric strength greater than 500 volts per 25.4 microns, (iii) an isothermal weight loss under inert conditions of less than 2% at 500° C. over 30 minutes, and (iv) an eₘₐₓ of less than 1.05% at 7.4-8 MPa.

10. An assembly in accordance with claim 1, wherein the polyimide film comprises two or more layers.

11. An assembly in accordance with claim 1, wherein the polyimide film is reinforced with a thermally stable, inorganic: fabric, paper, sheet, scrim or a combination thereof.

12. An assembly comprising:
A) a polyimide film comprising:
a) a polyimide in an amount from 40 to 95 weight percent of the polyimide film, the polyimide being derived from:
i) at least one aromatic dianhydride, at least 85 mole percent of said aromatic dianhydride being a rigid rod type dianhydride, and
ii) at least one aromatic diamine, at least 85 mole percent of said aromatic diamine being a rigid rod type diamine; and
b) a filler that:
i) has an average diameter of less than 100 nanometers in all dimensions; and
ii) is present in an amount from 5 to 60 weight percent of the total weight of the polyimide film,
the polyimide film having a thickness from 8 to 150 microns,
B) an electrode supported by said polyimide film.
